(19) United States
(12) Patent Application Publication
(10) Pub. No.: US 2025/0022503 A1
(43) Pub. Date: Jan. 16, 2025

(54) PROCESSING-IN-MEMORY DEVICES

(71) Applicant: SK hynix Inc., Icheon-si Gyeonggi-do (KR)

(72) Inventor: Hae Rang CHOI, Icheon-si Gyeonggi-do (KR)

(73) Assignee: SK hynix Inc., Icheon-si Gyeonggi-do (KR)

(21) Appl. No.: 18/420,019

(22) Filed: Jan. 23, 2024

(30) Foreign Application Priority Data
Jul. 14, 2023 (KR) 10-2023-0092071

(51) Int. Cl. G11C 11/4091; G11C 11/408; G11C 11/4096

(52) U.S. Cl. CPC G11C 11/4091; G11C 11/4085; G11C 11/4096

(57) ABSTRACT

A processing-in-memory device includes a memory cell array including a plurality of memory cells coupled to a plurality of word lines and a plurality of bit lines, a sense amplifier circuit coupled to the plurality of bit lines, and a control circuit configured to perform a row data copy operation that copies data of a first word line to a second word line, among the plurality of word lines. The control circuit is configured to sequentially perform operations according to an active control signal, a row close control signal, and a row open control signal to perform the row data copy operation.

### CROSS-REFERENCE TO RELATED APPLICATIONS

The present application claims priority under 35 U.S.C. 119(a) to Korean Patent Application No. 10-2023-0092071, filed on Jul. 14, 2023, in the Korean Intellectual Property Office, which is incorporated herein by reference in its entirety.

### BACKGROUND

### 1. Technical Field

Various embodiments of the present disclosure relate to processing-in-memory (PIM) devices.

### 2. Related Art

Recently, interest in artificial intelligence (AI) has been rapidly increasing not only in the information technology (IT) industry, but also in the overall industries such as finance and medical care. Accordingly, introduction of artificial intelligence, more precisely, deep learning, is being considered and prototyped in various fields. In general, the deep learning collectively refers to technologies that effectively learn deep neural networks (DNNs) or deep networks with an increased number of layers compared to existing neural networks and utilize the deep neural networks (DNNs) or deep networks for pattern recognition or inference.

One of the backgrounds and causes of such a wide interest in deep learning may be the performance improvement of processors that perform operations. To improve the performance of the artificial intelligence, as many as hundreds of layers of neural network are accumulated and learned. Such a trend has continued in recent years, and as a result, the amount of operations required for hardware that actually performs operations has increased exponentially. Moreover, in the case of the existing hardware system in which a memory and a processor are separated, the performance improvement of artificial intelligence hardware is hindered due to limitations in the amount of data communication between the memory and the processor. Recently, to solve this problem, a processing-in-memory device in which operating circuits and memory circuits are integrated in a semiconductor chip itself has been used as a neural network computing device.

### SUMMARY

A processing-in-memory (PIM) device according to an embodiment of the present disclosure may include a memory cell array including a plurality of memory cells coupled to a plurality of word lines and a plurality of bit lines, a sense amplifier circuit coupled to the plurality of bit lines, and a control circuit configured to perform a row data copy operation that copies data of a first word line to a second word line, among the plurality of word lines. The control circuit may be configured to sequentially perform operations according to an active control signal, a row close control signal, and a row open control signal to perform the row data copy operation.

A processing-in-memory (PIM) device according to an embodiment of the present disclosure may include sub memory cell arrays, each including a plurality of memory cells coupled to a plurality of word lines and a plurality of bit lines, the sub memory cell arrays including a first sub memory cell array including a plurality of first memory cells coupled to a plurality of first word lines and a plurality of first bit lines and a second sub memory cell array including a plurality of second memory cells coupled to a plurality of second word lines and a plurality of second bit lines, a first sense amplifier circuit coupled to the plurality of first bit lines of the first sub memory cell array, a second sense amplifier circuit coupled to the plurality of second bit lines of the second sub memory cell array, a copy circuit configured to, based on a copy control signal, control an electrical connection of the plurality of first bit lines and the plurality of second bit lines, a copy control circuit configured to generate the copy control signal based on a first row open control signal, a first row close control signal, a second row open control signal, and a second row close control and configured to transmit the copy control signal to the copy circuit, and a control circuit configured to control a row data copy operation between the sub memory cell arrays by copying data of the first memory cells of a source word line, which is one of the plurality of first word lines, to the second memory cells of a target word line, which is one of the plurality of second word lines. The control circuit may be configured to sequentially perform operations between the sub memory cell arrays according to a first active control signal, the first row close control signal, the second row open control signal, and the copy control signal to perform the row data copy operation.

### BRIEF DESCRIPTION OF THE DRAWINGS

FIG. 1 is a block diagram illustrating a processing-in-memory device according to an embodiment of the present disclosure.

FIG. 2 is a flowchart illustrating a row data copy operation in the processing-in-memory device of FIG. 1.

FIG. 3 illustrates the operation of the processing-in-memory device according to operation 210 in the flowchart of FIG. 2.

FIG. 4 illustrates the operation of the processing-in-memory device according to operation 220 in the flowchart of FIG. 2.

FIG. 5 illustrates the operation of the processing-in-memory device according to operation 230 in the flowchart of FIG. 2.

FIG. 6 illustrates the operation of the processing-in-memory device according to operation 240 in the flowchart of FIG. 2.

FIG. 7 is a flowchart illustrating the operation that processes operation data and operation result data in the processing-in-memory device of FIG. 1.

FIG. 8 illustrates the operation of the processing-in-memory device according to operation 330 in the flowchart of FIG. 7.

FIG. 9 illustrates the operation of the processing-in-memory device according to operation 340 in the flowchart of FIG. 7.

FIG. 10 illustrates the operation of the processing-in-memory device according to operation 350 in the flowchart of FIG. 7.

FIG. 11 is a block diagram illustrating a processing-in-memory device according to another embodiment of the present disclosure.

FIG. 12 is a flowchart illustrating a row data copy operation between sub memory cell arrays in the processing-in-memory device of FIG. 11.

FIG. 13 illustrates the operation of the processing-in-memory device according to operation 610 in the flowchart of FIG. 12.

FIG. 14 illustrates the operation of the processing-in-memory device according to operation 620 in the flowchart of FIG. 12.

FIG. 15 illustrates the operation of the processing-in-memory device according to operation 630 in the flowchart of FIG. 12.

FIG. 16 illustrates the operation of the processing-in-memory device according to operation 640 in the flowchart of FIG. 12.

### DETAILED DESCRIPTION OF THE EMBODIMENTS

In the following description of embodiments, it will be understood that the terms “first” and “second” are intended to identify elements, but not used to define a particular number or sequence of elements. In addition, when an element is referred to as being located “on,” “over,” “above,” “under,” or “beneath” another element, it is intended to mean relative positional relationship, but not used to limit certain cases for which the element directly contacts the other element, or at least one intervening element is present between the two elements. Accordingly, the terms such as “on,” “over,” “above,” “under,” “beneath,” “below,” and the like that are used herein are for the purpose of describing particular embodiments only and are not intended to limit the scope of the present disclosure. Further, when an element is referred to as being “connected” or “coupled” to another element, the element may be electrically or mechanically connected or coupled to the other element directly, or may be electrically or mechanically connected or coupled to the other element indirectly with one or more additional elements between the two elements.

Moreover, when a parameter is referred to as being “predetermined,” it may be intended to mean that a value of the parameter is determined in advance of when the parameter is used in a process or an algorithm. The value of the parameter may be set when the process or the algorithm starts or may be set during a period in which the process or the algorithm is executed.

A logic “high” level and a logic “low” level may be used to describe logic levels of electric signals. A signal having a logic “high” level may be distinguished from a signal having a logic “low” level. For example, when a signal having a first voltage corresponds to a signal having a logic “high” level, a signal having a second voltage may correspond to a signal having a logic “low” level. In an embodiment, the logic “high” level may be set as a voltage level which is higher than a voltage level of the logic “low” level. Meanwhile, logic levels of signals may be set to be different or opposite according to embodiment. For example, a certain signal having a logic “high” level in one embodiment may be set to have a logic “low” level in another embodiment.

Various embodiments of the present disclosure will be described hereinafter in detail with reference to the accompanying drawings. However, the embodiments described herein are for illustrative purposes only and are not intended to limit the scope of the present disclosure.

In various embodiments described below, a dynamic random access memory (DRAM) device is taken as an example of a memory device, but it is obvious that the present disclosure is not limited thereto. For example, the present disclosure is equally applicable to a static random access memory (SRAM) device, a synchronous DRAM (SDRAM) device, a double data rate synchronous DRAM (DDR SDRAM, DDR2 SDRAM, DDR3 SDRAM, etc.) device, a graphics double data rate synchronous DRAM (GDDR, GDDR2, GDDR3, etc.) device, a quad data rate DRAM (QDR DRAM) device, a RAMBUS XDR DRAM (XDR DRAM) device, a fast page mode DRAM (FPM DRAM) device, a video DRAM (VDRAM) device, an extended data output type DRAM (EDO DRAM) device, a burst EDO DRAM (BEDO DRAM) device, a multi-bank DRAM (MDRAM) device, a synchronous graphic RAM (SGRAM) device, and/or other types of DRAM devices.

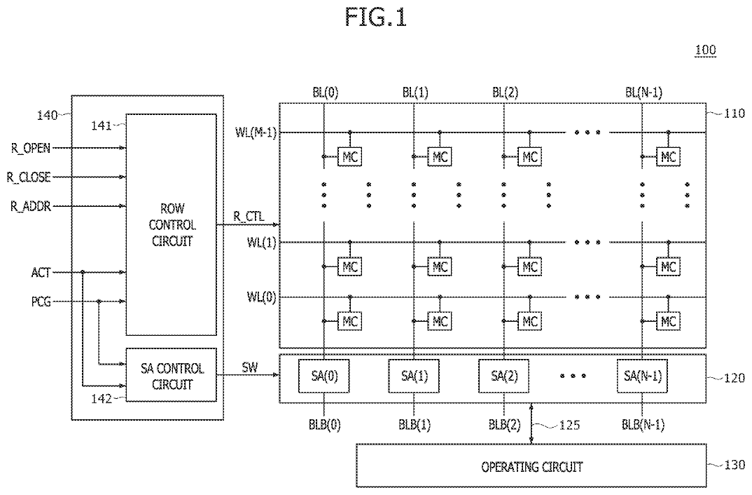

FIG. 1 is a block diagram illustrating a processing-in-memory device 100 according to an embodiment of the present disclosure. Referring to FIG. 1, the processing-in-memory device 100 may include a memory cell array 110, a sense amplifier circuit 120, an operating circuit 130, and a control circuit 140.

The memory cell array 110 may include a plurality of memory cells MCs coupled to a plurality of rows and a plurality of columns. In this embodiment, the plurality of memory cells MCs may be disposed at intersections between the plurality of rows and the plurality of columns according to an open bit line structure. However, this is merely an example, and the plurality of memory cells MCs may be disposed in a zigzag form at the intersections between the plurality of rows and the plurality of columns according to a folded bit line structure. A plurality of word lines WLs may be disposed in the plurality of rows of the memory cell array 110. The memory cells MCs disposed in one row may share one word line WL. Accordingly, hereinafter, the terms “row” and “word line” of the memory cell array 110 may be used interchangeably. In this embodiment, the memory cell array 110 may include “M” rows (where “M” is a natural number), and accordingly, first to “M”^{th} word lines WL(0)-WL(M−1) may be disposed in the memory cell array 110. A plurality of bit lines BLs may be disposed in the plurality of columns of the memory cell array 110. The memory cells MCs disposed in one column may share the same bit line BL. Accordingly, hereinafter, the terms “column” and “bit line” of the memory cell array 110 may be used in the same meaning. In this embodiment, the memory cell array 110 may include “N” columns (where “N” is a natural number), and accordingly, first to “N”^{th} bit lines BL(0)-BL(N−1) may be disposed in the memory cell array 110. In an example, the memory cell MC may be a DRAM cell. The DRAM cell may be composed of an access transistor that is switched through a signal applied to the word line WL and a storage capacitor that can be connected to the bit line BL through the access transistor.

As illustrated in FIG. 1, “N” memory cells respectively coupled to the first to “N”^{th} bit lines BL(0)-BL(N−1) may be coupled to the first row of the memory cell array 110, that is, the first word line WL(0). “N” memory cells respectively coupled to the first to “N”^{th} bit lines BL(0)-BL(N−1) may be coupled to the second row of the memory cell array 110, that is, the second word line WL(1). Similarly, “N” memory cells respectively coupled to the first to “N”^{th} bit lines BL(0)-BL(N−1) may be coupled to the “M”^{th} row of the memory cell array 110, that is, the “M”^{th} word line WL(M−1). Among the first to “M”^{th} word lines WL(0)-WL(M−1) of the memory cell array 110, the word line WL designated by a row address signal R_ADDR may be selected by a row control signal R_CTL.

The sense amplifier circuit 120 may perform sense and amplification operations for the data stored in the memory cells MCs of the selected word line WL, among the first to “M”^{th} word lines WL(0)-WL(M−1) of the memory cell array 110. The sense and amplification operations performed by the sense amplifier circuit 120 may be performed by comparing voltages of the first to “N”^{th} bit lines BL(0)-BL(N−1) with a reference voltage and amplifying the voltages corresponding to the differences between the voltages of the first to “N”^{th} bit lines BL(0)-BL(N−1) and the reference voltage. After performing the sense and amplification operations, the sense amplifier circuit 120 may restore the charging status of the storage capacitors of the memory cells MCs of the selected word line WL. The sense amplifier circuit 120 may transmit data to the operating circuit 130 or receive data from the operating circuit 130 through a data transmission line 125.

The sense amplifier circuit 120 may include a plurality of sense amplifiers SAs, for example, first to “N”^{th} sense amplifiers SA(0)-SA(N−1). The first to “N”^{th} sense amplifiers SA(0)-SA(N−1) may be coupled to the first to “N”^{th} bit lines BL(0)-BL(N−1), respectively. In addition, the first to “N”^{th} sense amplifiers SA(0)-SA(N−1) may also be coupled to first to “N”^{th} bit line bars BLB(0)-BLB(N−1), respectively. In an example, the first to “N”^{th} bit line bars BLB(0)-BLB(N−1) may be the same as the first to “N”^{th} bit lines BL(0)-BL(N−1) of a neighboring memory cell array. The first to “N”^{th} bit line bars BLB(0)-BLB(N−1) may provide the reference voltage in the process of performing the sense and amplification operations of the first to “N”^{th} sense amplifiers SA(0)-SA(N−1). As illustrated in FIG. 1, the first sense amplifier SA(0) may be coupled to the first bit line BL(0) and the first bit line bar BLB(0). The second sense amplifier SA(1) may be coupled to the second bit line BL(1) and the second bit line bar BLB(1). The third sense amplifier SA(2) may be coupled to the third bit line BL(2) and the third bit line bar BLB(2). In addition, the “N”^{th} sense amplifier SA(N−1) may be coupled to the “N”^{th} bit line BL(N−1) and the “N”^{th} bit line bar BLB(N−1).

The sense amplifier circuit 120 may be enabled or disabled according to a logic level of a switching signal SW transmitted from a sense amplification (SA) control circuit 142 of the control circuit 140. For example, the sense amplifier circuit 120 may be enabled by the switching signal SW at a first logic level (hereinafter, referred to as a logic “high” level). Hereinafter, the switching signal SW of the logic “high” level may be referred to as a “switching-on signal”. When the switching-on signal is transmitted, all of the first to “N”^{th} sense amplifiers SA(0)-SA(N−1) of the sense amplifier circuit 120 may be turned on. The sense amplifier circuit 120 may be disabled by the switching signal SW at a second logic level (hereinafter, referred to as a logic “low” level). Hereinafter, the switching signal SW of the logic “low” level may be referred to as a “switching-off signal”. When the switching-off signal is transmitted, all of the first to “N”^{th} sense amplifiers SA(0)-SA(N−1) of the sense amplifier circuit 120 may be turned off. The sense amplifier circuit 120 may maintain a disabled status until an active control signal ACT at a logic “high” level is transmitted. When enabled by the active control signal ACT at a logic “high” level, the sense amplifier circuit 120 may maintain an enabled status until a precharge control signal PCG at a logic “high” level has been transmitted. When the precharge control signal PCG at a logic “high” level is transmitted, the sense amplifier circuit 120 may be disabled.

The operating circuit 130 may receive the data from the memory cell array 110 through the sense amplifier circuit 120 and may perform the operations using the received data. In an example, the operations performed by the operating circuit 130 may include an arithmetic operation, a logic operation, a shift operation, a complement operation, and the like. In an example, the operations performed by the operating circuit 130 may include a neural network operation, for example, a multiplication-and-accumulation (MAC) operation. The operating circuit 130 may transmit operation result data generated by the operations to the memory cell array 110 through the sense amplifier circuit 120.

The control circuit 140 may control the memory cell array 110 and the sense amplifier circuit 120. The control circuit 140 may control a read operation and a write operation for the memory cell array 110. In addition, the control circuit 140 may control a row data copy operation that copies data of the memory cells MCs of a source row (i.e., a source word line), among the plurality of rows of the memory cell array 110, to the memory cells MCs of a target row (i.e., a target word line). The control circuit 140 may enable or disable the sense amplifier circuit 120. The control circuit 140 may receive control signals, such as the active control signal ACT, the precharge control signal PCG, a row open control signal R_OPEN, a row close control signal R_CLOSE, and a row address signal R_ADDR. Although omitted in FIG. 1, the control circuit 140 may receive a read control signal and a write control signal as the control signals. Further, the control circuit 140 may also receive a column address signal.

In response to the active control signal ACT at a logic “high” level, the control circuit 140 may transmit a row control signal R_CTL, which activates the word line WL designated by the row address signal R_ADDR, to the memory cell array 110. In addition, in response to the active control signal ACT at a logic “high” level, the control circuit 140 may transmit the switching-on signal, which enables the sense amplifier circuit 120 as the switching signal SW, to the sense amplifier circuit 120. In response to the row open control signal R_OPEN at a logic “high” level, the control circuit 140 may transmit the row control signal R_CTL, which opens the word line WL designated by the row address signal R_ADDR, to the memory cell array 110. The access transistors of the memory cells MCs of the opened word line WL may be turned on. In response to the row close control signal R_CLOSE at a logic “high” level, the control circuit 140 may transmit the row control signal R_CTL, which closes the word line WL designated by the row address signal R_ADDR, to the memory cell array 110. The access transistors of the memory cells MCs of the closed word line WL may be turned off. In response to the precharge control signal PCG at a logic “high” level, the control circuit 140 may transmit the row control signal R_CTL, which closes the word line WL designated by the row address signal R_ADDR, to the memory cell array 110. In addition, in response to the precharge control signal PCG at a logic “high” level, the control circuit 140 may transmit the switching-off signal, which disables the sense amplifier circuit 120 as the switching signal SW, to the sense amplifier circuit 120. The control circuit 140 may perform the row data copy operation that copies all data of the source row of the memory cell array 110 to the target row by sequentially performing the operations according to the active control signal ACT at a logic “high” level, the row close control signal R_CLOSE at a logic “high” level, and the row open control signal R_OPEN at a logic “high” level.

The control circuit 140 may include a row control circuit 141 and the sense amplifier control circuit 142. The row control circuit 141 may receive the active control signal ACT, the precharge control signal PCG, the row open control signal R_OPEN, the row close control signal R_CLOSE, and the row address signal R_ADDR. The row control circuit 141 may generate and transmit the row control signal R_CTL to the memory cell array 110. The sense amplifier control circuit 142 may receive the active control signal ACT and the precharge control signal PCG. The sense amplifier control circuit 142 may transmit the switching signal SW to the sense amplifier circuit 120.

In response to the active control signal ACT at a logic “high” level, the row control circuit 141 may transmit the row control signal R_CRL that activates the source row designated by the row address signal R_ADDR, among the plurality of rows of the memory cell array 110, to the memory cell array 110. In response to the active control signal ACT at a logic “high” level, the sense amplifier control circuit 142 may transmit the switching-on signal that turns on the first to “N”^{th} sense amplifiers SA(0)-SA(N−1) of the sense amplifier circuit 120 as the switching signal SW to the sense amplifier circuit 120. The turned-on first to “N”^{th} sense amplifiers SA(0)-SA(N−1) may perform the sense and amplification operations for the activated source row. In response to the row close control signal R_CLOSE at a logic “high” level, the row control circuit 141 may transmit the row control signal R_CTL, which closes the source row, to the memory cell array 110. In response to the row open control signal R_OPEN at a logic “high” level, the row control circuit 141 may transmit the row control signal R_CTL, which opens the target row designated by the row address signal R_ADDR, among the plurality of rows of the memory cell array 110, to the memory cell array 110. In the target row opened by the row control signal R_CTL, the data of the source rows of the first to “N”^{th} sense amplifiers SA(0)-SA(N−1) may be equally stored, and accordingly, the row data copy operation may be completed. When the row data copy operation is completed, in response to the precharge control signal PCG at a logic “high” level, the sense amplifier control circuit 142 may transmit the switching-off signal, which disables the sense amplifier circuit 120 as the switching signal SW, to the sense amplifier circuit 120. Accordingly, all of the first to “N”^{th} sense amplifiers SA(0)-SA(N−1) of the sense amplifier circuit 120 may be turned off.

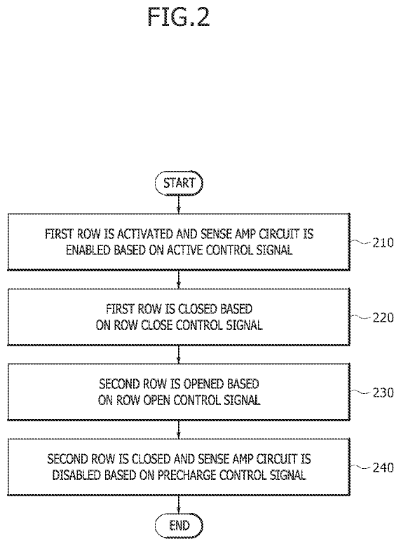

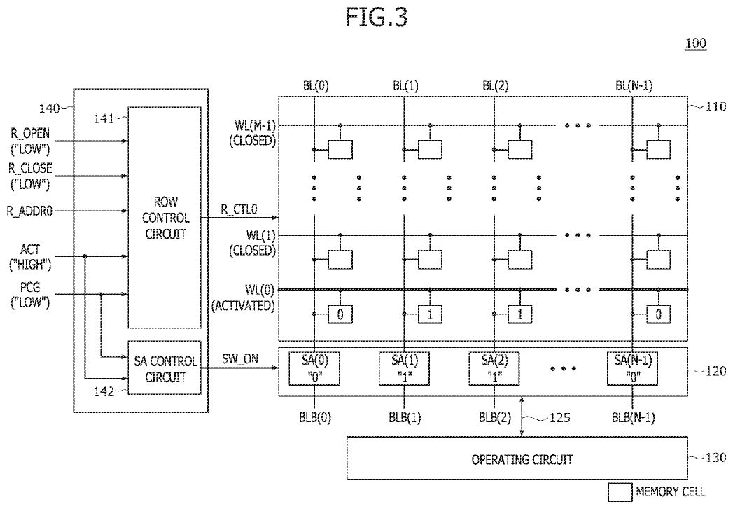

FIG. 2 is a flowchart illustrating the row data copy operation in the processing-in-memory device 100 of FIG. 1. In addition, FIGS. 3 to 6 illustrate each operation in the flowchart of FIG. 2. Hereinafter, the process of copying “N” bit data “011 . . . 0” of a source row, for example, the first word line WL(0) of the memory cell array 110 to a target row, for example, the second word line WL(1) of the memory cell array 110 will be exemplified. However, this is merely an example, and each of the first word line WL(0) and the second word line WL(1) in this example may be any one word line, among the first to “M”^{th} word lines WL(0)-WL(M−1) of the memory cell array 110.

Referring to FIG. 2, in operation 210, the first row, that is, the first word line WL(0) of the memory cell array 110, may be activated, and the sense amplifier circuit 120 may be enabled by the active control signal ACT. In more detail with reference to FIG. 3, the row control circuit 141 and the sense amplifier control circuit 142 of the control circuit 140 may receive the active control signal ACT at a logic “high” level. In addition, the row control circuit 141 of the control circuit 140 may receive a first row address signal R_ADDR0 designating the first word line WL(0) corresponding to the source row of the memory cell array 110. The precharge control signal PCG, the row open control signal R_OPEN, and the row close control signal R_CLOSE may all have a logic “low” level. In response to the active control signal ACT at a logic “high” level and the first row address signal R_ADDR0, the row control circuit 141 may generate and transmit a first row control signal R_CTL0, which activates the first word line WL(0) of the memory cell array 110, to the memory cell array 110. The first word line WL(0) among the first to “M”^{th} word lines WL(0)-WL(M−1) of the memory cell array 110 may be activated by the first row control signal R_CTL0. On the other hand, all of the first to “M”^{th} word lines WL(0)-WL(M−1), except for the first word line WL(0), may remain closed.

In response to the active control signal ACT at a logic “high” level, the sense amplifier control circuit 142 may transmit a switching-on signal SW_ON, which enables the sense amplifier circuit 120, to the sense amplifier circuit 120. The first to “N”^{th} sense amplifiers SA(0)-SA(N−1) of the sense amplifier circuit 120 may all be turned on by the switching-on signal SW_ON. As all of the first to “N”^{th} sense amplifiers SA(0)-SA(N−1) are turned on, bit values of “N” bit data “011 . . . 0” stored in the first word line WL(0) of the memory cell array 110 may be transmitted to the first to “N”^{th} sense amplifiers SA(0)-SA(N−1), respectively. Accordingly, the “N” bit data of “011 . . . 0” may be stored in the first to “N”^{th} sense amplifiers SA(0)-SA(N−1), respectively.

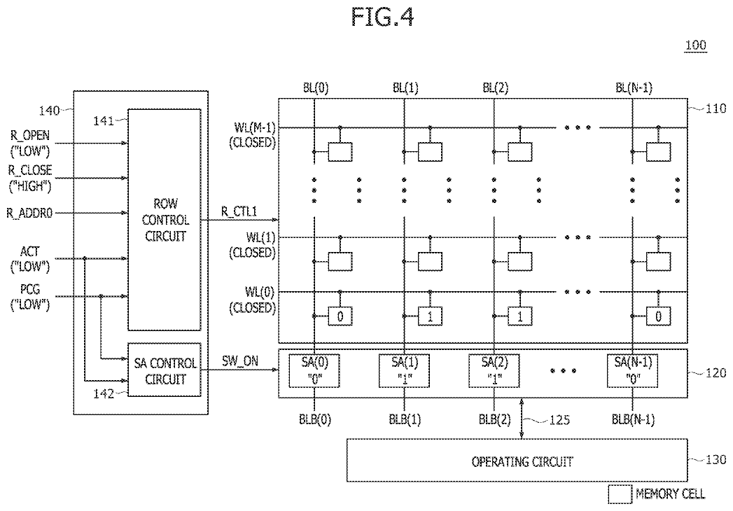

Next, in operation 220, the first row, that is, the first word line WL(0) of the memory cell array 110, may be closed by the row close control signal R_CLOSE. In more detail with reference to FIG. 4, the row control circuit 141 of the control circuit 140 may receive the row close control signal R_CLOSE at a logic “high” level and the first row address signal R_ADDR0. The logic level of the active control signal ACT may be changed from a logic “high” level to a logic “low” level. Both the precharge control signal PCG and the row open control signal R_OPEN may be maintained at a logic “low” level. In response to the row close control signal R_CLOSE at a logic “high” level and the first row address signal R_ADDR0, the row control circuit 141 may generate and transmit a second row control signal R_CTL1, which closes the first word line WL(0) designated by the first row address signal R_ADDR0, among the first to “M”^{th} word lines WL(0)-WL(M−1) to the memory cell array 110. In this example, the first row address signal R_ADDR0 may be transmitted to the row control circuit 141, together with the row close control signal R_CLOSE, but this is merely an example. In another example, the first row address signal R_ADDR0 may be transmitted along with the previous active control signal ACT and may be temporarily stored in the row control circuit 141. The status of the first word line WL(0) of the memory cell array 110 may be changed from an activated status to a closed status by the second row control signal R_CTL1. That is, all of the first to “M”^{th} word lines WL(0)-WL(M−1) of the memory cell array 110 may be in the closed status.

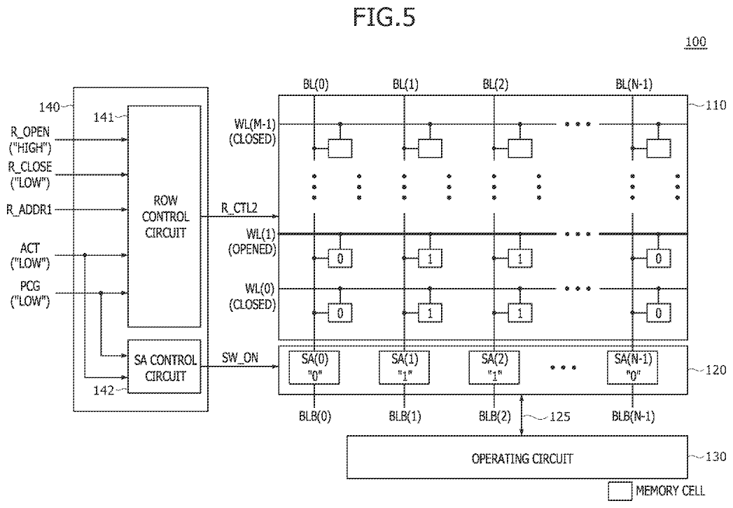

Next, in operation 230, the second row, that is, the second word line WL(1) of the memory cell array 110, may be opened by the row open control signal R_OPEN. In more detail with reference to FIG. 5, the row control circuit 141 of the control circuit 140 may receive the row open control signal R_OPEN at a logic “high” level. In addition, the row control circuit 141 of the control circuit 140 may receive a second row address signal R_ADDR1 designating the second word line WL(1) corresponding to the target row of the memory cell array 110. The logic level of the row close control signal R_CLOSE may be changed from a logic “high” level to a logic “low” level. Both the active control signal ACT and the precharge control signal PCG may be maintained at a logic “low” level. In response to the row open control signal R_OPEN at a logic “high” level and the second row address signal R_ADDR1, the row control circuit 141 may generate and transmit a third row control signal R_CTL2, which opens the second word line WL(1) designated by the second row address signal R_ADDR1, among the first to “M”^{th} word lines WL(0)-WL(M−1) of the memory cell array 110, to the memory cell array 110. The status of the second word line WL(1) of the memory cell array 110 may be changed from a closed status to an opened status by the third row control signal R_CTL2. On the other hand, all of the first to “M”^{th} word lines WL(0)-WL(M−1), except for the second word line WL(1), may be in the closed status.

Because the first to “N”^{th} sense amplifiers SA(0)-SA(N−1) of the sense amplifier circuit 120 maintain the turned-on status while storing the “N” bit data “011 . . . 0”, the “N” bit data “011 . . . 0” may be transmitted to the memory cells coupled to the second word line WL(1) of the memory cell array 110. Accordingly, “N” bit values of “011 . . . 0” may be stored in the “N” memory cells of the second word line WL(1), respectively. That is, the “N” bit data “011 . . . 0” stored in the memory cells of the first word line WL(0) may be copied in the memory cells of the second word line WL(1).

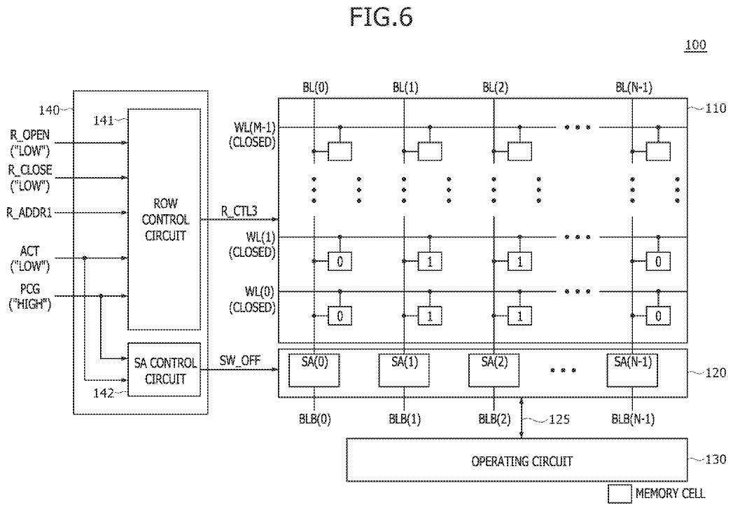

Next, in operation 240, the second row, that is, the second word line WL(1) of the memory cell array 110, may be closed, and the sense amplifier circuit 120 may be disabled by the precharge control signal PCG. In more detail with reference to FIG. 6, the row control circuit 141 of the control circuit 140 may receive the precharge control signal PCG at a logic “high” level and the second row address signal R_ADDR1. The sense amplifier control circuit 142 of the control circuit 140 may receive the precharge control signal PCG at a logic “high” level. The logic level of the row open control signal R_OPEN may be changed from a logic “high” level to a logic “low” level. Both the active control signal ACT and the row close control signal R_CLOSE may be maintained at a logic “low” level. In response to the precharge control signal PCG at a logic “high” level and the second row address signal R_ADDR1, the row control circuit 141 may generate and transmit a fourth row control signal R_CTL3, which closes the second word line WL(1) of the memory cell array 110, to the memory cell array 110. Accordingly, all of the first to “M”^{th} word lines WL(0)-WL(M−1) may be in the closed status. In response to the precharge control signal PCG at a logic “high” level, the sense amplifier control circuit 142 may transmit a switching-off signal SW_OFF, which disables the sense amplifier circuit 120 as the switching signal, to the sense amplifier circuit 120. All of the first to “N”^{th} sense amplifiers SA(0)-SA(N−1) of the sense amplifier circuit 120 may be turned off by the switching-off signal SW_OFF.

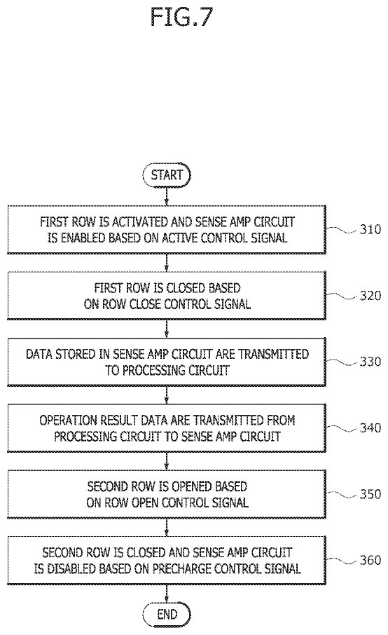

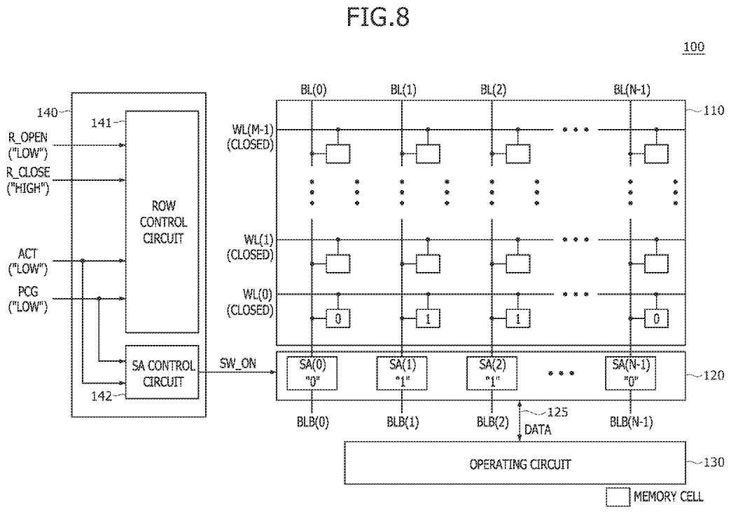

FIG. 7 is a flowchart illustrating the operation that processes operation data and operation result data in the processing-in-memory device 100 of FIG. 1. In addition, FIGS. 8 to 10 illustrate the operations of the processing-in-memory device 100 according to operations 330 to 350 in the flowchart of FIG. 7. Hereinafter, a process in which “N” bit data “011 . . . 0” of the first word line WL(0) of the memory cell array 110 is transmitted to the operating circuit 130 and “N” bit operation result data “110 . . . 1” is stored in the second word line WL(1) of the memory cell array 110 will be exemplified. However, this is merely an example, and each of the first word line WL(0) and the second word line WL(1) in this example may be any one of the first to “M”^{th} word lines WL(0)-WL(M−1) of the memory cell array 110.

Referring to FIG. 7, in operation 310, the first row, that is, the first word line WL(0) of the memory cell array 110, may be activated, and the sense amplifier circuit 120 may be enabled by the active control signal ACT. The process of operation 310 may be performed in the same manner as the process described with reference to FIG. 3. Accordingly, the bit values of the “N” bit data “011 . . . 0” stored in the first word line WL(0) of the memory cell array 110 may be stored in the first to “N”^{th} sense amplifiers SA(0)-SA(N−1) of the sense amplifier circuit 120, respectively, based on the first row control signal (R_CTL0 of FIG. 3). Next, in operation 320, the first row, that is, the first word line WL(0), may be closed by the row close control signal R_CLOSE. The process of operation 320 may be performed in the same manner as the process described with reference to FIG. 4. Accordingly, all of the first to “M”^{th} word lines WL(0)-WL(M−1) of the memory cell array 110 may be closed by the second row control signal (R_CTL1 of FIG. 4).

Next, in operation 330, the data stored in the sense amplifier circuit 120, that is, the “N” bit data “011 . . . 0”, may be transmitted to the operating circuit 130. In more detail with reference to FIG. 8, the “N” bit data “011 . . . 0” stored in the sense amplifier circuit 120 may be transmit to the operating circuit 130 through the data transmission line 125. Although not shown in FIG. 8, the transmission of the “N” bit data “011 . . . 0” from the sense amplifier circuit 120 to the operating circuit 130 may be performed in response to an operation control signal that controls the operations in the operating circuit 130. The operating circuit 130 receiving the “N” bit data “011 . . . 0” from the sense amplifier circuit 120 may perform operations using the “N” bit data “011 . . . 0”. In an example, the operating circuit 130 may also receive other data required for the operations from a storage device other than the sense amplifier circuit 120, for example, a buffer memory device. The operating circuit 130 may perform the operations to generate operation result data.

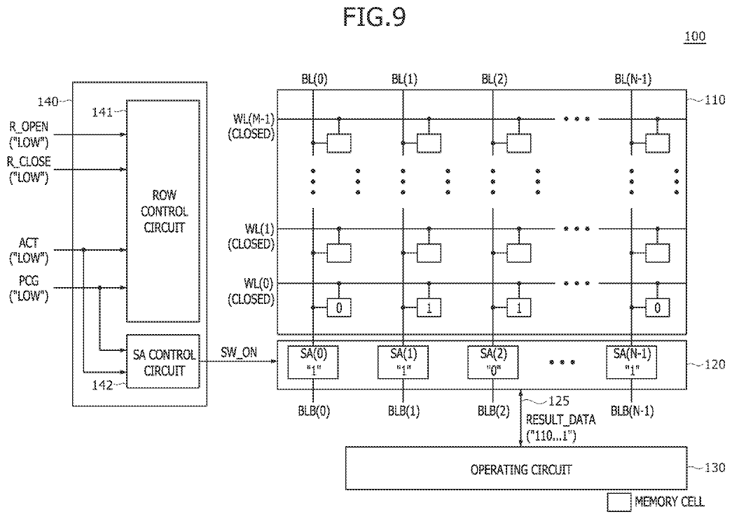

Next, in operation 340, the operating circuit 130 may transmit the operation result data to the sense amplifier circuit 120. In more detail with reference to FIG. 9, the operating circuit 130 may transmit the operation result data RESULT_DATA, for example, “N” bit operation result data “110 . . . 1”, to the sense amplifier circuit 120 through the data transmission line 125. Although not shown in FIG. 9, for the transmission of the operation result data RESULT_DATA to the sense amplifier circuit 120, the operating circuit 130 may receive an operation result data output control signal that controls the output of the operation result data RESULT_DATA.

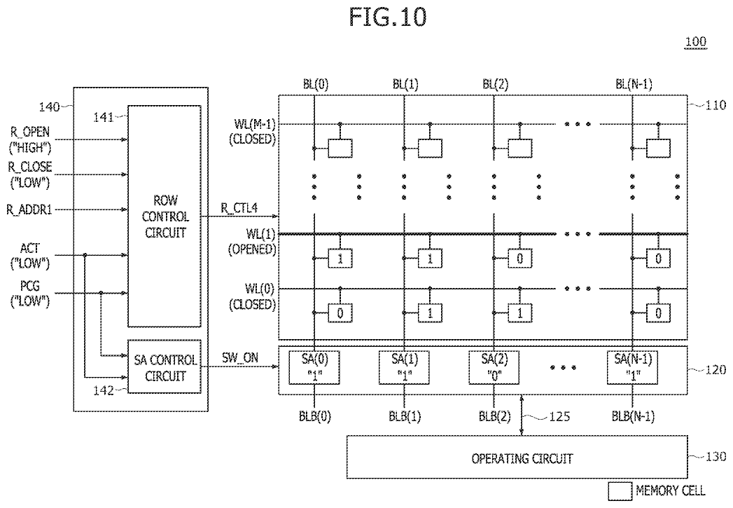

Next, in operation 350, the second row, that is, the second word line WL(1), may be opened by the row open control signal R_OPEN. In more detail with reference to FIG. 10, the row control circuit 141 of the control circuit 140 may receive the row open control signal R_OPEN at a logic “high” level. In addition, the row control circuit 141 of the control circuit 140 may receive a second row address signal R_ADDR1 designating the second word line WL(1) corresponding to the target row in which the operation result data RESULT_DATA is to be stored, among the rows of the memory cell array 110. In response to the row open control signal R_OPEN at a logic “high” level and the second row address signal R_ADDR1, the row control circuit 141 may generate and transmit a fifth row control signal R_CTL4, which opens the second word line WL(1) designated by the second row address signal R_ADDR1, among the first to “M”^{th} word lines WL(0)-WL(M−1) of the memory cell array 110, to the memory cell array 110. By the fifth row control signal R_CTL4, the status of the second word line WL(1) of the memory cell array 110 may be changed from a closed status to an opened status. On the other hand, all of the first to “M”^{th} word lines WL(0)-WL(M−1), except for the second word line WL(1), may maintain the closed status.

Because the first to “N”^{th} sense amplifiers SA(0)-SA(N−1) of the sense amplifier circuit 120 maintain the turned-on status while storing the “N” bit operation result data “110 . . . 1”, the “N” bit operation result data “110 . . . 1” may be transmitted to the memory cells coupled to the second word line WL(1) of the memory cell array 110. Accordingly, the “N” bit values of “110 . . . 1” may be respectively stored in the “N” memory cells of the second word line WL(1). That is, the “N” bit operation result data “110 . . . 1” generated by the operating circuit 130 may be stored in the memory cells of the second word line WL(1).

Next, in operation 360, the second row, that is, the second word line WL(1) of the memory cell array 110, may be closed and the sense amplifier circuit 120 may be disabled by the precharge control signal PCG. The process of operation 360 may be performed in the same manner as described with reference to FIG. 6. Accordingly, based on the fourth row control signal (R_CTL3 of FIG. 6), all of the first to “M”^{th} word lines WL(0)-WL(M−1) of the memory cell array 110 may be closed, and all of the first to “N”^{th} sense amplifiers SA(0)-SA(N−1) of the sense amplifier circuit 120 may be turned off.

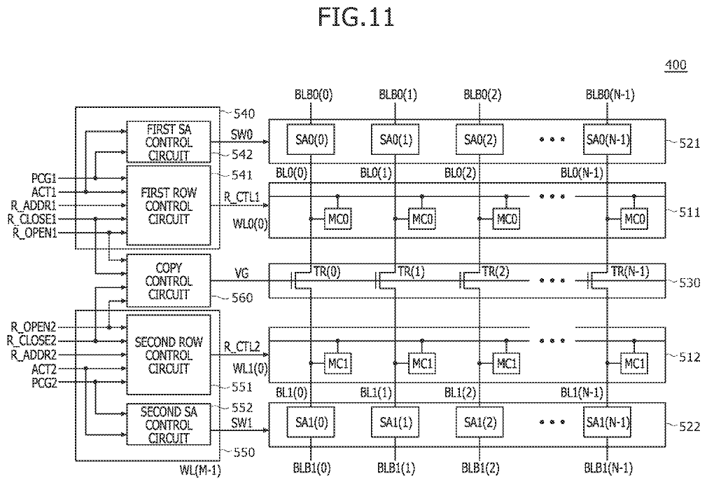

FIG. 11 is a block diagram illustrating a processing-in-memory device 400 according to another embodiment of the present disclosure. First and second operating circuits respectively coupled to a first sense amplifier circuit and a second sense amplifier circuit are omitted in FIG. 11 to avoid increased complexities in the drawing. The description for the operating circuit 130 described with reference to FIG. 1 may be equally applied to the omitted first and second operating circuits.

Referring to FIG. 11, the processing-in-memory device 400 may include a plurality of sub memory cell arrays, for example, a first sub memory cell array 511 and a second sub memory cell array 512. The processing-in-memory device 400 may include a first sense amplifier circuit 521 coupled to the first sub memory cell array 511 and a second sense amplifier circuit 522 coupled to the second sub memory cell array 512. The processing-in-memory device 400 may include a control circuit composed of a first control circuit 540 and a second control circuit 550. The first control circuit 540 may control the first sub memory cell array 511 and the first sense amplifier circuit 521. The second control circuit 550 may control the second sub memory cell array 512 and the second sense amplifier circuit 522. The first control circuit 540 may include a first row control circuit 541 controlling the first sub memory cell array 511 and a first sense amplifier control circuit 542 controlling the first sense amplifier circuit 521. The second control circuit 550 may include a second row control circuit 551 controlling the second sub memory cell array 512 and a second sense amplifier control circuit 552 controlling the second sense amplifier circuit 522. The processing-in-memory device 400 may include a copy circuit 530 for a row data copy operation between the first sub memory cell array 511 and the second sub memory cell array 512 and may include a copy control circuit 560 that controls the copy circuit 530.

Each of the first sub memory cell array 511 and the second sub memory cell array 512 may have the same configuration as the memory cell array (110 of FIG. 1) described with reference to FIG. 1. Accordingly, the first sub memory cell array 511 may include memory cells MCOs disposed at intersections between “M” first word lines WL0s and “N” first bit lines BL0s. Similarly, the second sub memory cell array 512 may also include memory cells MC1s disposed at intersections between “M” second word lines WL1s and “N” second bit lines BL1s. To avoid increased complexities in the drawing, FIG. 11 illustrates only one word line (hereinafter, referred to as a “source word line”) WL0(0), among the “N” first word lines WL0s of the first sub memory cell array 511. Similarly, only one word line (hereinafter, referred to as a “target word line”) WL1(0), among the “N” second word lines WL1s of the second sub memory cell array 512, is illustrated. In this example, each of the first sub memory cell array 511 and the second sub memory cell array 512 have an open bit line structure. Accordingly, when another sub memory cell array adjacent to the first sub memory cell array 511 is accessed, the first bit lines BL0s of the first sub memory cell array 511 may function as bit line bars BLB0s. Similarly, when another sub memory cell array adjacent to the second sub memory cell array 512 is accessed, the second bit lines BL1s of the second sub memory cell array 512 may also function as bit line bars BLB1s. Accordingly, in this example, the bit lines BLs and the bit line bars BLBs do not need to be structurally distinguished.

The first sense amplifier circuit 521 may be coupled to the “N” first bit lines BL0(0)-BL0(N−1) of the first sub memory cell array 511. In addition, the first sense amplifier circuit 521 may also be coupled to the “N” first bit line bars BLB0(0)-BLB0(N−1) of another sub memory cell array adjacent to the first sub memory cell array 511. The first sense amplifier circuit 521 may include “N” first sense amplifiers SAO(0)-SAO(N−1). The “N” first sense amplifiers SAO(0)-SAO(N−1) may be collectively turned on or turned off by a first switching signal SW0 transmitted from the first sense amplifier control circuit 542 of the first control circuit 540. The description for the sense amplifier circuit 120, described with reference to FIG. 1, may be equally applied to the first sense amplifier circuit 521.

The second sense amplifier circuit 522 may be coupled to “N” second bit lines BL1(0)-BL1(N−1) of the second sub memory cell array 512. In addition, the second sense amplifier circuit 522 may also be coupled to “N” bit line bars BLB1(0)-BLB1(N−1) of another sub memory cell array adjacent to the second sub memory cell array 512. The second sense amplifier circuit 522 may include “N” second sense amplifiers SA1(0)-SA1(N−1). The “N” second sense amplifiers SA1(0)-SA1(N−1) may be collectively turned on or turned off by a second switching signal SW1 transmitted from the second sense amplifier control circuit 552 of the second control circuit 550. The description for the sense amplifier circuit 120, described with reference to FIG. 1, may be equally applied to the second sense amplifier circuit 522.

The copy circuit 530 may be disposed between the first sub memory cell array 511 and the second sub memory cell array 512. The copy circuit 530 may include a plurality of transistors, for example, first to “N”^{th} transistors TR(0)-TR(N−1). In an example, each of the first to “N”^{th} transistors TR(0)-TR(N−1) may be an NMOS transistor. The sources and drains of the first to “N”^{th} transistors TR(0)-TR(N−1) may be coupled to the first to “N”^{th} first bit lines BL0(0)-BL0(N−1) of the first sub memory cell array 511 and the first to “N”^{th} second bit lines BL1(0)-BL1(N−1) of the second sub memory cell array 512, respectively. Specifically, the drain of the first transistor TR(0) may be coupled to the first bit line BL0(0) of the first column of the first sub memory cell array 511, and the source of the first transistor TR(0) may be coupled to the second bit BL1(0) of the first column of the second sub memory cell array 512. In a similar manner, the drain of the second transistor TR(1) may be coupled to the first bit line BL0(1) of the second column of the first sub memory cell array 511, and the source of the second transistor TR(1) may be coupled to the second bit line BL1(1) of the second column of the second sub memory cell array 512. In a similar manner, the drain of the third transistor TR(2) may be coupled to the first bit line BL0(2) of the third column of the first sub memory cell array 511, and the source of the third transistor TR(2) may be coupled to the second bit line BL1(2) of the third column of the second sub memory cell array 512. In a similar manner, the drain of the “N”^{th} transistor TR(N−1) may be coupled to the first bit line BL0(N−1) of the “N”^{th} column of the first sub memory cell array 511, and the source of the “N”^{th} transistor TR(N−1) may be coupled to the second bit line BL1(N−1) of the “N”^{th} column of the second sub memory cell array 512. The gates of the first to “N”^{th} transistors TR(0)-TR(N−1) may be commonly coupled to the copy control circuit 560. Accordingly, the first to “N”^{th} transistors TR(0)-TR(N−1) may commonly receive a gate signal VG from the copy control circuit 560. In an example, when the gate signal VG at a logic “high” level is transmitted, all of the first to “N”^{th} transistors TR(0)-TR(N−1) may be turned on. On the other hand, when the gate signal VG at a logic “low” level is transmitted, all of the first to “N”^{th} transistors TR(0)-TR(N−1) may be turned off.

The first row control circuit 541 of the first control circuit 540 may receive a first active control signal ACT1, a first precharge control signal PCG1, a first row open control signal R_OPEN1, a first row close control signal R_CLOSE1, and a first row address signal R_ADDR1. The first row control circuit 541 may generate and transmit a first row control signal R_CTL1 to the first sub memory cell array 511. The first sense amplifier control circuit 542 of the first control circuit 540 may receive the first precharge control signal PCG1 and the first active control signal ACT1 and may generate and transmit a first switching signal SW0 to the first sense amplifier circuit 521. The operations of the first row control circuit 541 and the first sense amplifier control circuit 542 of the first control circuit 540 may be the same as the operations of the row control circuit 141 and the sense amplifier control circuit 142 of the control circuit 140, described with reference to FIG. 1.

The second row control circuit 551 of the second control circuit 550 may receive a second active control signal ACT2, a second precharge control signal PCG2, a second row open control signal R_OPEN2, a second row close control signal R_CLOSE2, and a second row address signal R_ADDR2. The second row control circuit 551 may generate and transmit a second row control signal R_CTL2 to the second sub memory cell array 512. The second sense amplifier control circuit 552 of the second control circuit 550 may receive the second precharge control signal PCG2 and the second active control signal ACT2 and may generate and transmit a second switching signal SW1 to the second sense amplifier circuit 522. The operations of the second row control circuit 551 and the second sense amplifier control circuit 552 of the second control circuit 550 may be the same as those of the row control circuit 141 and the sense amplifier control circuit 142 of the control circuit 140, described with reference to FIG. 1.

The copy control circuit 560 may receive the first row open control signal R_OPEN1, the first row close control signal R_CLOSE1, the second row open control signal R_OPEN2, and the second row close control signal R_CLOSE2. The copy control circuit 560 may generate and transmit a gate signal VG at a logic “high” level or a logic “low” level to the gates of the first to “N”^{th} transistors TR(0)-TR(N−1) of the copy circuit 530. When the first row close control signal R_CLOSE1 at a logic “high” level and the second row open control signal R_OPEN2 at a logic “high” level are sequentially transmitted, the copy control circuit 560 may change the logic level of the gate signal VG from a logic “low” level to a logic “high” level at a time point at which the second row open control signal R_OPEN2 of the logic “high” level is transmitted. In addition, when the second row close control signal R_CLOSE2 at a logic “high” level and the first row open control signal R_OPEN1 at a logic “high” level are sequentially transmitted, the copy control circuit 560 may change the logic level of the gate signal VG from a logic “low” level to a logic “high” level at a time point at which the first row open control signal R_OPEN1 of the logic “high” level is transmitted. When the first row open control signal R_OPEN1 at a logic “high” level and the first row close control signal R_CLOSE1 at a logic “high” level are sequentially transmitted, the copy control circuit 560 may change the logic level of the gate signal VG from a logic “high” level to a logic “low” level at a time point at which the first row close control signal R_CLOSE1 of the logic “high” level is transmitted. In addition, when the second row open control signal R_OPEN2 at a logic “high” level and the second row close control signal R_CLOSE2 at a logic “high” level are sequentially transmitted, the copy control circuit 560 may change the logic level of the gate signal VG from a logic “high” level to a logic “low” level at a time point at which the second row close control signal R_CLOSE2 of the logic “high” level is transmitted. In other cases, the gate signal VG output from the copy control circuit 560 may maintain the logic “low” level.

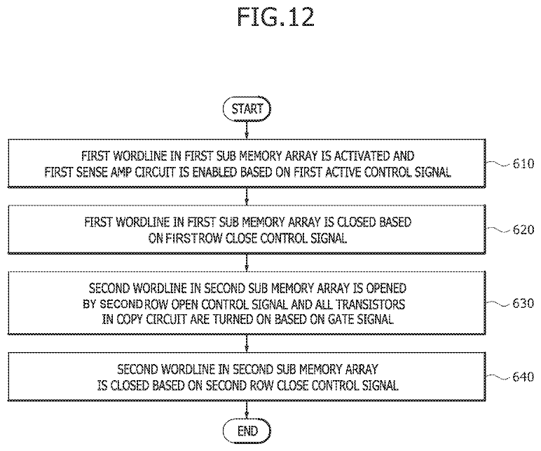

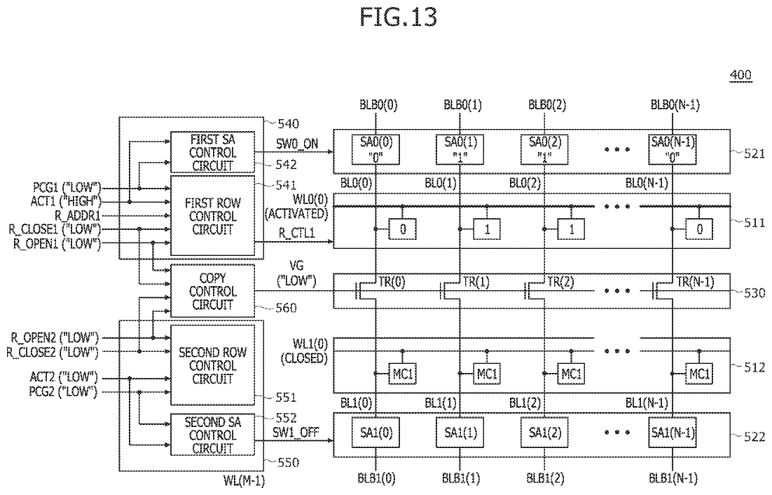

FIG. 12 is a flowchart illustrating a row data copy operation between sub memory cell arrays 511 and 512 in the processing-in-memory device 400 of FIG. 11. In addition, FIGS. 13 to 16 illustrate the operations of the processing-in-memory device according to operations 610 to 640 in the flowchart of FIG. 12. Hereinafter, a process of copying “N” bit data “011 . . . 0” stored in a source row (i.e., source word line) of the first sub memory cell array 511 to a target row (i.e., target word line) of the second sub memory cell array 512 will be taken as an example. The following description may be equally applied to the process of copying row data from the source row of the second sub memory cell array 512 to the target row of the first sub memory cell array 511.

Referring to FIG. 12, first, in operation 610, the source word line of the first sub memory cell array 511 may be activated based on the first active control signal ACT1, and the first sense amplifier circuit 521 may be enabled. In more detail with reference to FIG. 13, the first active control signal ACT1 at a logic “high” level and the first row address signal R_ADDR1 designating the source word line WL0(0) may be transmitted to the first control circuit 540. All of the first precharge control signal PCG1, the first row open control signal R_OPEN1, the first row close control signal R_CLOSE1, the second active control signal ACT2, the second precharge control signal PCG2, the second row open control signal R_OPEN2, and the second row close control signal R_CLOSE2 may be at a logic “low” level. The first active control signal ACT1 at a logic “high” level may be commonly transmitted to the first row control circuit 541 and the first sense amplifier control circuit 542 of the first control circuit 540. The first row address signal R_ADDR1 may be transmitted to the first row control circuit 541.

In response to the first active control signal ACT1 at a logic “high” level, the first row control circuit 541 may generate and transmit the first row control signal R_CTL1, which activates the source word line WL0(0) designated by the first row address signal R_ADDR1, to the first sub memory cell array 511. Accordingly, the source word line WL0(0) of the first sub memory cell array 511 may be activated. In response to the first active control signal ACT1 at a logic “high” level, the first sense amplifier control circuit 542 may transmit a switching-on signal SW0_ON to the first sense amplifier circuit 521. Accordingly, all the “N” sense amplifiers SA0(0)-SA0(N−1) of the first sense amplifier circuit 521 may be turned on. In this status, the bit values of the “N” bit data “011 . . . 0” of the source word line WL0(0) may be sensed and amplified in the “N” sense amplifiers SA0(0)-SA0(N−1) of the sense amplifier circuit 521, respectively. That is, the “N” bit data “011 . . . 0” of the source word line WL0(0) may be equally stored in the first sense amplifier circuit 521.

In the process of performing operation 610, because the first row close control signal R_CLOSE1, the first row open control signal R_OPEN1, the second row close control signal R_CLOSE2, and the second row open control signal R_OPEN2 are all at a logic “low” level, the copy control circuit 560 may transmit the gate signal VG at a logic “low” level to the copy circuit 530. Accordingly, all the “N” transistors TR(0)-TR(N−1) of the copy circuit 530 may be turned off, and as a result, the electrical connection between the first sub memory cell array 511 and the second sub memory cell array 512 may be disconnected.

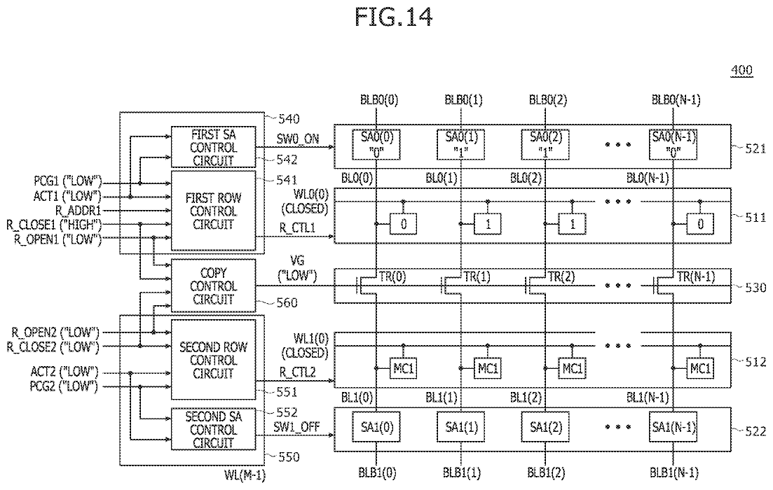

Next, in operation 620, the source word line WL0(0) of the first sub memory cell array 511 may be closed based on the first row close control signal R_CLOSE1. In more detail with reference to FIG. 14, the first row close control signal R_CLOSE1 at a logic “high” level and the first row address signal R_ADDR1 designating the source word line WL0(0) may be transmitted to the first control circuit 540. All of the first active control signal ACT1, the first precharge control signal PCG1, the first row open control signal R_OPEN1, the second active control signal ACT2, the second precharge control signal PCG2, the second row open control signal R_OPEN2, and the second row close control signal R_CLOSE2 may be at a logic “low” level. The first row close control signal R_CLOSE1 at a logic “high” level may be commonly transmitted to the first row control circuit 541 of the first control circuit 540 and the copy control circuit 560. The first row address signal R_ADDR1 may be transmitted to the first row control circuit 541.

In response to the first row close control signal R_CLOSE1 at a logic “high” level, the first row control circuit 541 may generate and transmit the first row control signal R_CTL1, which closes the source word line WL0(0) designated by the first row address signal R_ADDR1, to the first sub memory cell array 511. Accordingly, the status of the source word line WL0(0) of the first sub memory cell array 511 may be changed from an activated status to a closed status. The first sense amplifier control circuit 542 may maintain the first switching-on signal SW0_ON, and accordingly, the “N” bit data “011 . . . 0” stored in the “N” sense amplifiers SA0(0)-SA0(N−1) of the first sense amplifier circuit 521 may remain the same. Even in the process of performing operation 620, the copy control circuit 560 may transmit the gate signal VG at a logic “low” level to the copy circuit 530. Accordingly, all of the “N” transistors TR(0)-TR(N−1) of the copy circuit 530 may be turned off, and as a result, the electrical connection between the first sub memory cell array 511 and the second sub memory cell array 512 may remain disconnected.

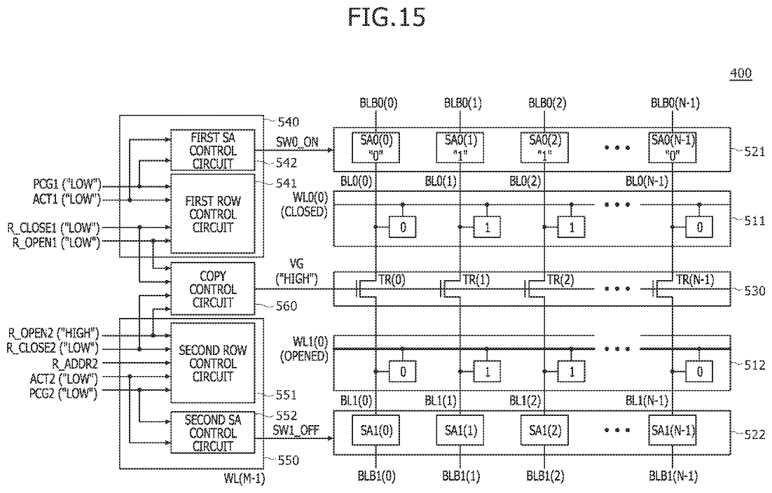

Next, in operation 630, the target word line WL1(0) of the second sub memory cell array 512 may be opened based on the second row open control signal R_OPEN2, and all of the transistors TR(0)-TR(N−1) of the copy circuit 530 may be turned on based on the gate signal VG. In more detail with reference to FIG. 15, the logic level of the first row close control signal R_CLOSE1 transmitted to the first control circuit 540 may be changed from a logic “high” level to a logic “low” level. Because all of the first active control signal ACT1, the first precharge control signal PCG1, the first row open control signal R_OPEN1, and the first row close control signal R_CLOSE1 are at a logic “low” level, the first row control circuit 541 might not transmit the first row control signal to the first sub memory cell array 511. The first sense amplifier control circuit 542 may maintain the transmission of the first switching-on signal SW0_ON to the first sense amplifier circuit 521. The second control circuit 550 may receive the second row open control signal R_OPEN2 at a logic “high” level and the second row address signal R_ADDR2 designating the target word line WL1(0). All of the second active control signal ACT2, the second precharge control signal PCG2, and the second row close control signal R_CLOSE2 may be at a logic “low” level. The second row open control signal R_OPEN2 at a logic “high” level may be commonly transmitted to the second row control circuit 551 of the second control circuit 550 and the copy control circuit 560. The second row address signal R_ADDR2 may be transmitted to the second row control circuit 551.

In response to the second row open control signal R_OPEN2 at a logic “high” level, the second row control circuit 551 may generate and transmit the second row control signal R_CTL2, which opens the target word line WL1(0) designated by the second row address signal R_ADDR2, to the second sub memory cell array 512. Accordingly, the status of the target word line WL1(0) of the second sub memory cell array 512 may be changed from a closed status to an opened status. Although omitted in FIG. 15, all other word lines of the second sub memory cell array 512 may maintain the closed status. The second sense amplifier control circuit 552 may maintain the second switching-off signal SW1_OFF, and accordingly, all of the “N” sense amplifiers SA1(0)-SA1(N−1) of the second sense amplifier circuit 522 may remain turned off.

The copy control circuit 560 may receive the first row open control signal R_OPEN1 at a logic “low” level, the first row close control signal R_CLOSE1 at a logic “low” level, the second row open control signal R_OPEN2 at a logic “high” level, and the second row close control R_CLOSE2 at a logic “low” level. As the first row close control signal R_CLOSE1 at a logic “high” level is transmitted in operation 620, and then the second row open control signal R_OPEN2 at a logic “high” level is transmitted in operation 630, the copy control circuit 560 may change the logic level of the gate signal VG from a logic “low” level to a logic “high” level. Accordingly, all of the “N” transistors TR(0)-TR(N−1) of the copy circuit 530 may be turned on, and as a result, the “N” bit lines BL1(0)-BL1(N−1) of the second sub memory cell array 512 may be electrically coupled to the “N” sense amplifiers SA0(0)-SA0(N−1) of the first sense amplifier circuit 521, respectively. In this status, the “N” bit data “011 . . . 0” stored in the “N” sense amplifiers SA0(0)-SA0(N−1) of the first sense amplifier circuit 521 may be transmitted to the memory cells of the target word line WL1(0) of the second sub memory cell array 512. As a result, the “N” bit data “011 . . . 0” stored in the memory cells of the source word line WL0(0) of the first sub memory cell array 511 may be copied to the memory cells of the target word line WL1(0) of the second sub memory cell array 512 through the first sense amplifier circuit 521 and the copy circuit 530.

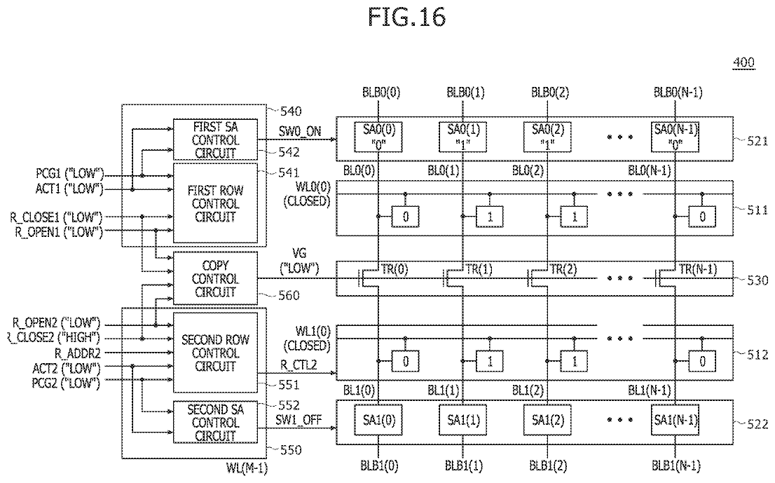

Next, in operation 640, the target word line WL1(0) of the second sub memory cell array 512 may be closed based on the second row close control signal R_CLOSE2. In more detail with reference to FIG. 16, the logic levels of the first active control signal ACT1, the first precharge control signal PCG1, the first row open control signal R_OPEN1, and the first row close control signal R_CLOSE1 transmitted to the first control circuit 540 may all maintain the logic “low” level. Accordingly, the first row control circuit 541 might not transmit the first row control signal to the first sub memory cell array 511, and the first sense amplifier control circuit 542 may maintain the transmission of the first switching-on signal SW0_ON to the first sense amplifier circuit 521. The second control circuit 550 may receive the second row close control signal R_CLOSE2 at a logic “high” level and the second row address signal R_ADDR2 designating the target word line WL1(0). All of the second active control signal ACT2, the second precharge control signal PCG2, and the second row open control signal R_OPEN2 may be at a logic “low” level. The second row close control signal R_CLOSE2 at a logic “high” level may be commonly transmitted to the second row control circuit 551 of the second control circuit 550 and the copy control circuit 560. The second row address signal R_ADDR2 may be transmitted to the second row control circuit 551.

In response to the second row close control signal R_CLOSE2 at a logic “high” level, the second row control circuit 551 may generate and transmit the second row control signal R_CTL2, which closes the target word line WL1(0) designated by the second row address signal R_ADDR2, to the second sub memory cell array 512. Accordingly, the status of the target word line WL1(0) of the second sub memory cell array 512 may be changed from an opened status to a closed status. The second sense amplifier control circuit 552 may maintain the second switching-off signal SW1_OFF, and accordingly, the “N” sense amplifiers SA1(0)-SA1(N−1) of the second sense amplifier circuit 522 may remain turned off.

The copy control circuit 560 may receive the first row open control signal R_OPEN1 at a logic “low” level, the first row close control signal R_CLOSE1 at a logic “low” level, the second row open control signal R_OPEN2 at a logic “low” level, and the second row close control signal R_CLOSE2 at a logic “high” level. As the second row open control signal R_OPEN2 at a logic “high” level is transmitted in operation 630 and then the second row close control signal R_CLOSE2 at a logic “high” level is transmitted in operation 640, the copy control circuit 560 may change the logic level of the gate signal VG from a logic “high” level to a logic “low” level. Accordingly, the status of each of the “N” transistors TR(0)-TR(N−1) of the copy circuit 530 may be changed from a turned-on status to a turned-off status, and as a result, the electrical connection between the first sub memory cell array 511 and the second sub memory cell array 512 may be disconnected.

Although not shown in FIG. 16, through the processes of operations 610 to 640 of FIG. 12, after the “N” bit data “011 . . . 0” stored in the memory cells of the source word line WL0(0) of the first sub memory cell array 511 is copied to the memory cells of the target word line WL1(0) of the second sub memory cell array 512, the first precharge control signal PCG1 at a logic “high” level may be provided to the first row control circuit 541 and the first sense amplifier control circuit 542 of the first control circuit 540. Accordingly, the bit lines BL0(0)-BL0(N−1) of the first sub memory cell array 511 may be charged with a reference voltage, and the first sense amplifier circuit 521 may be disabled.

Meanwhile, the row data copy operation, described with reference to FIGS. 2 to 6, may be equally applied to the first sub memory cell array 511 and the second sub memory cell array 512 of the processing-in-memory device 400. In addition, the operation that transmits data to the operating circuits and storing operation result data to the memory cell array, described with reference to FIGS. 7 to 10, may also be applied to the first sub memory cell array 511 and the second sub memory cell array 512 of the processing-in-memory device 400.

A limited number of possible embodiments for the present teachings have been presented above for illustrative purposes. Those of ordinary skill in the art will appreciate that various modifications, additions, and substitutions are possible. While this patent document contains many specifics, these should not be construed as limitations on the scope of the present teachings or of what may be claimed, but rather as descriptions of features that may be specific to particular embodiments. Certain features that are described in this patent document in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

What is claimed is:

1. A processing-in-memory (PIM) device comprising:
a memory cell array including a plurality of memory cells coupled to a plurality of word lines and a plurality of bit lines;
a sense amplifier circuit coupled to the plurality of bit lines; and
a control circuit configured to perform a row data copy operation that copies data of a first word line to a second word line, among the plurality of word lines,
wherein the control circuit is configured to sequentially perform operations according to an active control signal, a row close control signal, and a row open control signal to perform the row data copy operation.

2. The processing-in-memory (PIM) device of claim 1, wherein the control circuit is configured to activate the first word line and to enable the sense amplifier circuit, based on the active control signal, the data of the memory cells of the first word line being sensed and amplified in the sense amplifier circuit.

3. The processing-in-memory (PIM) device of claim 2, wherein, based on the row close control signal, the control circuit is configured to control the first word line to be closed.

4. The processing-in-memory (PIM) device of claim 3, wherein, based on the row open control signal, the control circuit is configured to control the second word line to be opened, the data sensed and amplified in the sense and amplifier circuit being stored in the memory cells of the second word line.

5. The processing-in-memory (PIM) device of claim 4, wherein the control circuit is configured to disable the sense amplifier circuit based on a precharge control signal.

6. The processing-in-memory (PIM) device of claim 1,
wherein the sense amplifier circuit includes a plurality of sense amplifiers respectively coupled to the plurality of bit lines,
wherein the control circuit includes:
a row control circuit configured to, in response to the active control signal at a first logic level, transmit a first row control signal for activating the first word line designated by a first row address signal to the memory cell array; and
a sense amplifier control signal configured to, in response to the active control signal at the first logic level, transmit a switching-on signal for turning on the sense amplifiers to the sense amplifier circuit, and
wherein the turned-on sense amplifiers are configured to sense and amplify data of the memory cells of the activated first word line.

7. The processing-in-memory (PIM) device of claim 6, wherein the row control circuit is configured to:
transmit a second row control signal for controlling the first word line to be closed to the memory cell array in response to the row close control signal at the first logic level, and
transmit a third row control signal for controlling the second word line to be opened to the memory cell array in response to the row open control signal at the first logic level, the data sensed and amplified by the second amplifiers being stored in the memory cells of the second word line.

8. The processing-in-memory (PIM) device of claim 7, wherein the sense amplifier control circuit is configured to transmit a switching-off signal for disabling the sense amplifier circuit to the sense amplifier circuit in response to the precharge control signal at the first logic level.

9. The processing-in-memory (PIM) device of claim 1, further comprising an operating circuit configured to receive data of the memory cell array to perform operations,
wherein the operating circuit is configured to receive the data sensed and amplified by the second amplifiers between a time point at which the first word line is closed and a time point at which the second word line is opened and configured to perform the operations using the received data.

10. The processing-in-memory (PIM) device of claim 9,
wherein the operating circuit is configured to transmit operation result data generated as a result of performing the operations to the sense amplifiers, and
wherein the row control circuit is configured to, in response to the row open control signal at the first logic level to the memory cell array, transmit a third row control signal for controlling a third word line designated by a third row address signal to be opened, the operation result data transmitted to the sense amplifiers being stored in memory cells of the third word line.

11. A processing-in-memory (PIM) device comprising:
sub memory cell arrays, each including a plurality of memory cells coupled to a plurality of word lines and a plurality of bit lines, the sub memory cell arrays including a first sub memory cell array including a plurality of first memory cells coupled to a plurality of first word lines and a plurality of first bit lines and a plurality of second sub memory cell array including a plurality of second memory cells coupled to a plurality of second word lines and a plurality of second bit lines;
a first sense amplifier circuit coupled to the plurality of first bit lines of the first sub memory cell array;
a second sense amplifier circuit coupled to the plurality of second bit lines of the second sub memory cell array;
a copy circuit configured to, based on a copy control signal, control an electrical connection of the plurality of first bit lines and the plurality of second bit lines;
a copy control circuit configured to generate the copy control signal based on a first row open control signal, a first row close control signal, a second row open control signal, and a second row close control and configured to transmit the copy control signal to the copy circuit; and
a control circuit configured to control a row data copy operation between the sub memory cell arrays by copying data of the first memory cells of a source word line, which is one of the plurality of first word lines, to the second memory cells of a target word line, which is one of the plurality of second word lines,
wherein the control circuit is configured to sequentially perform operations between the sub memory cell arrays according to a first active control signal, the first row close control signal, the second row open control signal, and the copy control signal to perform the row data copy operation.

12. The processing-in-memory (PIM) device of claim 11, wherein the control circuit is configured to:
control the first sub memory cell array and the first sense amplifier circuit in response to the first active control signal at a first logic level, the source word line of the first sub memory cell array being activated and the first sense amplifier circuit being enabled,
control the first sub memory cell array in response to the first row close signal at the first logic level, the source word line of the first sub memory cell array being closed;
control the second sub memory cell array, the target word line of the second sub memory cell array being opened, and control the copy circuit, the first bit lines and the second bit lines being electrically connected, in response to the second row open control signal at the first logic level, and
control the second sub memory cell array in response to the second row close control signal at the first logic level, the target word line of the second sub memory cell array being closed.

13. The processing-in-memory (PIM) device of claim 11, wherein the control circuit includes:
a first control circuit configured to receive the first active control signal, a first precharge control signal, the first row open control signal, and the first row close control signal and configured to generate and transmit a first row control signal and a first switching signal to the first sub memory cell array and the first sense amplifier circuit, respectively; and
a second control circuit configured to receive a second active control signal, a second precharge control signal, the second row open control signal, and the second row close control signal and configured to generate and transmit a second row control signal and a second switching signal to the second sub memory cell array and the second sense amplifier circuit, respectively.

14. The processing-in-memory (PIM) device of claim 13,
wherein the first control circuit includes:
a first row control circuit configured to generate the first row control signal based on the first active control signal, the first precharge control signal, the first row open control signal, and the first row close control signal and configured to transmit the first row control signal to the first sub memory cell array; and
a first sense amplifier control circuit configured to generate the first switching signal based on the first active control signal and the first precharge control signal and configured to transmit the first switching signal to the first sense amplifier circuit, and
wherein the second control circuit includes:
a second row control circuit configured to generate the second row control signal based on the second active control signal, the second precharge control signal, the second row open control signal, and the second row close control signal and configured to transmit the second row control signal to the second sub memory cell array; and
a second sense amplifier control circuit configured to generate the second switching signal based on the second active control signal and the second precharge control signal and configured to transmit the second switching signal to the second sense amplifier circuit.

15. The processing-in-memory (PIM) device of claim 14,
wherein the first row control circuit is configured to:
transmit the first row control signal for activating the source word line to the first sub memory cell array, in response to the first active control signal at a first logic level,
transmit the first row control signal for closing the source word line to the first sub memory cell array, in response to the first precharge control signal at the first logic level,
transmit the first row control signal for opening the source word line to the first sub memory cell array, in response to the first row open control signal at the first logic level, and
transmit the first row control signal for closing the source word line to the first sub memory cell array, in response to the first row close control signal at the first logic level, and
wherein the second row control circuit is configured to:
transmit the second row control signal for activating the target word line to the second sub memory cell array, in response to the second active control signal at the first logic level,
transmit the second row control signal for closing the target word line to the second sub memory cell array, in response to the second precharge control signal at the first logic level,
transmit the second row control signal for opening the target word line to the second sub memory cell array, in response to the second row open control signal at the first logic level, and
transmit the second row control signal for closing the target word line to the second sub memory cell array, in response to the second row close control signal at the first logic level.

16. The processing-in-memory (PIM) device of claim 15,
wherein the first sense amplifier control circuit is configured to:
transmit the first switching signal for enabling the first sense amplifier circuit to the first sense amplifier circuit, in response to the first active control signal at the first logic level, and
transmit the first switching signal for disabling the first sense amplifier circuit to the first sense amplifier circuit, in response to the first precharge control signal at the first logic level, and
wherein the second sense amplifier control circuit is configured to:
transmit the second switching signal for enabling the second sense amplifier circuit to the second sense amplifier circuit, in response to the second active control signal at the first logic level, and
transmit the second switching signal for disabling the second sense amplifier circuit to the second sense amplifier circuit, in response to the second precharge control signal at the first logic level.

17. The processing-in-memory (PIM) device of claim 16,
wherein the copy circuit includes transistors, and
wherein drains of the transistors are coupled to the first bit lines of the first sub memory cell array, sources of the transistors are coupled to the second bit lines of the second sub memory cell array, and gates of the transistors receive the copy control signal in common.

18. The processing-in-memory (PIM) device of claim 17, wherein the copy control circuit is configured to:
transmit the copy control signal at the first logic level for turning on the transistors to the copy circuit in synchronization with a time point at which the second row open control signal at the first logic level is transmitted, when the first row close control signal at the first logic level and the second row open control signal at the first logic level are transmitted successively, and
transmit the copy control signal at a second logic level for turning off the transistors to the copy circuit in synchronization with a time point at which the second row close control signal at the first logic level is transmitted, when the second row open control signal at the first logic level and the second row close control signal at the first logic level are transmitted successively.

19. The processing-in-memory (PIM) device of claim 17, wherein the copy control circuit is configured to:
transmit the copy control signal at the first logic level for turning on the transistors to the copy circuit in synchronization with a time point at which the first row open control signal at the first logic level is transmitted, when the second row close control signal at the first logic level and the first row open control signal at the first logic level are transmitted successively, and
transmit the copy control signal at a second logic level for turning off the transistors to the copy circuit in synchronization with a time point at which the first row close control signal at the first logic level is transmitted, when the first row open control signal at the first logic level and the first row close control signal at the first logic level are transmitted successively.

20. The processing-in-memory (PIM) device of claim 11, further comprising:
a first operating circuit configured to receive data of the first sub memory cell array to perform a first operation; and
a second operating circuit configured to receive data of the second sub memory cell array to perform a second operation.
